(19) United States
(12) Patent Application Publication
(10) Pub. No.: US 2007/0202679 A1
(43) Pub. Date: Aug. 30, 2007

(54) Method for fabricating contact plug of semiconductor device

(76) Inventors: Hyun Ahn, Kyoungki-do (KR); Ki-Won Nam, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/648,389

(22) Filed: Dec. 29, 2006

(30) Foreign Application Priority Data
Feb. 28, 2006 (KR) 2006-0019621
Dec. 1, 2006 (KR) 2006-0120794

(51) Int. Cl. H01L 21/44

(52) U.S. Cl. 438/597

(57) ABSTRACT

A method for fabricating a contact plug of a semiconductor device includes forming an insulation layer over a substrate, forming a hard mask over the insulation layer, etching the insulation layer to form a contact hole, removing the hard mask, forming a conductive layer to fill the contact hole, performing an etch back process on the conductive layer to form a contact plug, and performing an over etch process.

### CROSS-REFERENCES TO RELATED APPLICATIONS

The present invention claims priority of Korean patent application numbers 10-2006-0019621 and 10-2006-0120794, filed on Feb. 28, 2006 and Dec. 1, 2006, respectively, which are incorporated by reference in their entirety.

### BACKGROUND OF THE INVENTION

The present invention relates to a method for fabricating a semiconductor device, and more particularly, to a method for fabricating a contact plug (e.g., storage node contact plug) of a semiconductor device to reduce a self-align contact fail between a storage node and the storage node contact plug.

As a semiconductor device has been highly integrated, a height of an inter-layer insulation layer used for layer insulation gets increased. During etching the inter-layer insulation layer using a photoresist pattern as a mask, the photoresist pattern is damaged, and a pattern is deformed. As a result, the inter-layer insulation layer may not be easily etched. Accordingly, a method for using a hard mask beneath the photoresist pattern has been suggested.

FIGS. 1A to 1C illustrate a typical method for fabricating a storage node contact plug of a semiconductor device. As shown in FIG. 1A, an inter-layer insulation layer 12 is formed over an upper portion of a substrate 11, and a hard mask 13 for a storage node contact hole is formed over a certain portion of the inter-layer insulation layer 12.

The inter-layer insulation layer 12 is selectively etched using the hard mask 13 to form a plurality of storage node contact holes 14 exposing portions of the substrate 11. Reference denotation CD11 denotes a line width that each of the storage node contact holes initially has.

As shown in FIG. 1B, a photoresist layer 15 is formed over an entire surface of the substrate 11 including the storage node contact holes 14. Then, an etch back process is performed to remove the hard mask 13.

During removing the hard mask 13 through the etch back process after the storage node contact holes 14 are formed, top portions of the storage node contact holes 14 are damaged. The storage node contact holes with the damaged top portions are referred to as first storage node contact holes and denoted with a reference numeral 14A. The inter-layer insulation layer damaged by the first storage node contact holes 14A is referred to as a first patterned inter-layer insulation layer and denoted with a reference numeral 12A. As a result, the line width CD11 that each of the storage node contact holes 14 initially has gets widened, and each of the first storage node contact holes 14A has a line width CD12.

As shown in FIG. 1C, remaining portions of the photoresist layer 15 are removed, and a polysilicon layer is formed inside the first storage node contact holes 14A. Then, a planarization process is performed to form a plurality of storage node contact plugs 16.

As described above, each of the storage node contact holes 14 initially has the line width CD11. However, after the top portions of the storage node contact holes 14 are damaged, each of the first storage node contact holes 14A has the widened line width CD12. Due to the widened line width CD12, a spacing margin between the neighboring first storage node contact holes 14A may be reduced. Accordingly, a space S2 between the first storage node contact holes 14A is narrower than an initial space S1 between the neighboring storage node contact holes 14.

FIG. 2 is a micrograph illustrating limitations usually caused by the typical method. A reference letter ‘A’ shows that a top portion of an inter-layer insulation layer is damaged and thus, an etch profile of the inter-layer insulation layer, i.e., a profile of a top portion of a storage node contact hole, is not vertically formed but has a slope. The illustrated two arrows show that the top portion of the storage node contact hole has a line width CD22 larger than the line width CD21 of the initially formed storage node contact hole.

As described above, the etch back process performed to remove the hard mask defining the storage node contact hole produces damage on the top portion of the storage node contact hole. Thus, a line width of the top portion of the storage node contact hole gets widened.

After a conductive layer for storage node contact plugs is formed, a spacing margin between the neighboring storage node contact holes may be reduced due to the widened line width of the storage node contact plug. The reduced spacing margin may induce a bridge phenomenon between the storage node contact plugs and the storage node contact holes.

### SUMMARY OF THE INVENTION

Embodiments of the present invention are directed to provide a method for fabricating a storage node contact plug of a semiconductor device capable of disallowing a top portion of a storage node contact plug to be widened, and maintaining a space between neighboring storage node contact holes.

In accordance with an aspect of the present invention, there is provided a method for fabricating a contact plug of a semiconductor device, including: forming an insulation layer over a substrate; forming a hard mask over the insulation layer; etching the insulation layer to form a contact hole; removing the hard mask; forming a conductive layer to fill the contact hole; performing an etch back process on the conductive layer to form a contact plug; and performing an over etch process.

### BRIEF DESCRIPTION OF THE DRAWINGS

FIGS. 1A to 1C illustrate a typical method for fabricating a storage node contact plug of a semiconductor device.

FIG. 2 is a micrograph illustrating limitations usually caused by the typical method.

FIGS. 3A to 3D illustrate a method for fabricating a contact plug (e.g., storage node contact plug) of a semiconductor device in accordance with an embodiment of the present invention.

FIG. 4 is a micrograph illustrating an improved storage node contact plug in accordance with another embodiment of the present invention.

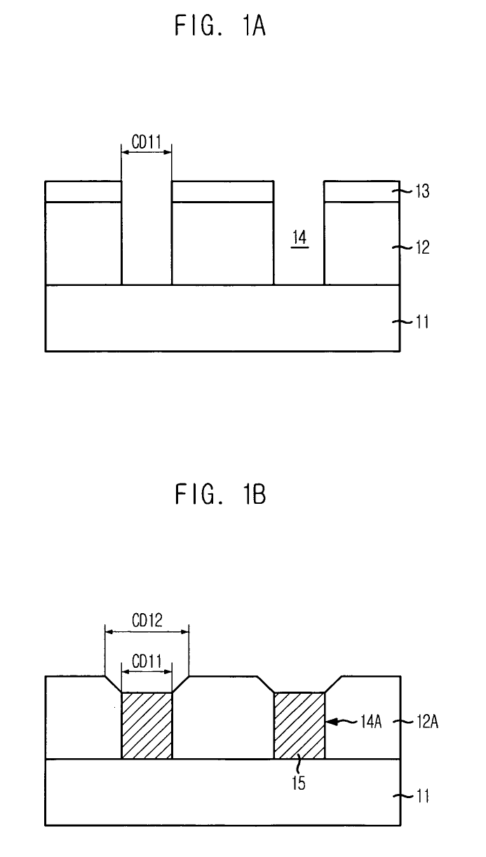

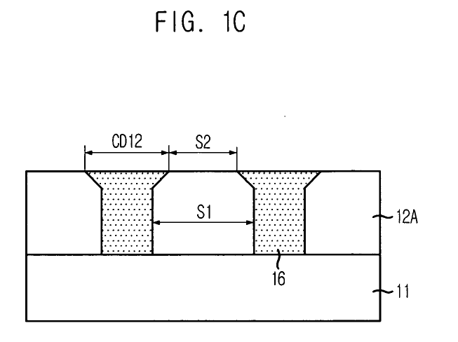

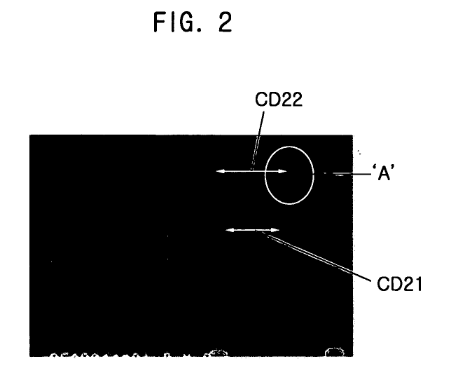

### DESCRIPTION OF SPECIFIC EMBODIMENTS

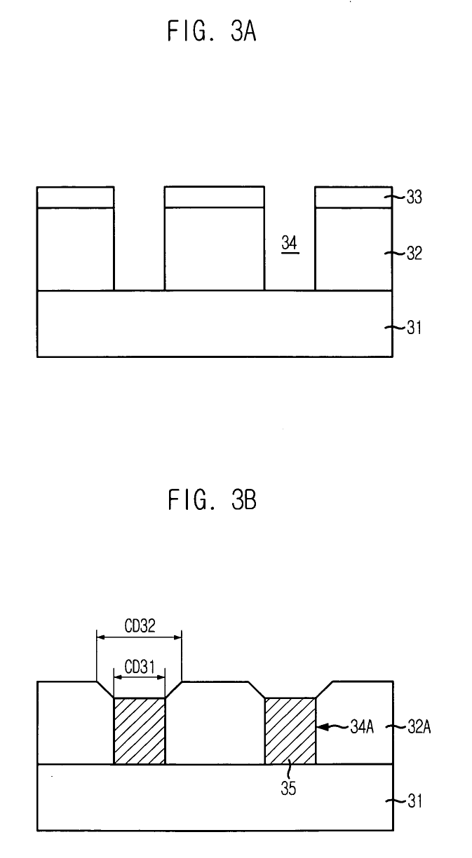

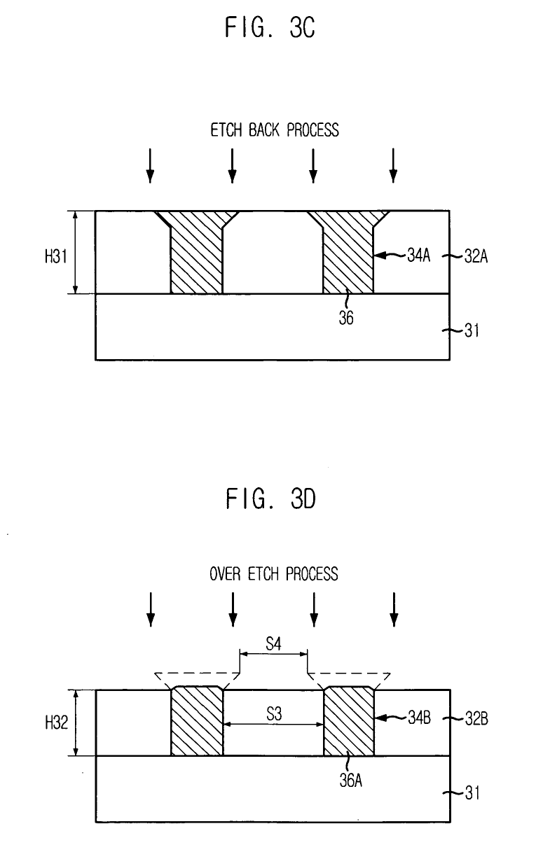

FIGS. 3A to 3D illustrate a method for fabricating a contact plug (e.g., storage node contact plug) of a semiconductor device in accordance with an embodiment of the present invention. As shown in FIG. 3A, an insulation layer 32 is formed over an upper portion of a substrate 31. A hard mask 33 for forming storage node contact holes is formed over a certain portion of the insulation layer 32. The hard mask 33 includes a silicon rich oxynitride (SRON) layer. The hard mask 33 is formed through an etching process using a photoresist pattern. The photoresist pattern is removed during forming subsequent storage node contact holes and thus, does not remain.

The insulation layer 32 is selectively etched using the hard mask 33 as an etch barrier to form a plurality of storage node contact holes 34 exposing portions of the substrate 31. The substrate 31 can be a source/drain junction region or a landing plug. The insulation layer 32 includes an oxide-based layer including a borophosphosilicate glass (BPSG) layer.

As show in FIG. 3B, a photoresist layer 35 is formed over an entire surface of the substrate 31 including the storage node contact holes 34 to remove the hard mask 33. An etch back process is performed and as a result, the hard mask 33 is removed. During removing the hard mask 33, top portions of the storage node contact holes 34 are damaged and thus, can be widened. The storage node contact holes with the damaged top portions are referred to as first storage node contact holes and denoted with a reference numeral 34A. The insulation layer damaged by the first storage node contact holes 34A is referred to as a first patterned insulation layer and denoted with a reference numeral 32A. Each of the storage node contact holes 34 initially has a line width CD31. However, each of the first storage node contact holes has a line width CD32.

As shown in FIG. 3C, remaining portions of the photoresist layer 35 are removed and then, a polysilicon layer is formed over an entire surface of the substrate 31 including the first storage node contact holes 34A. An etch back process is performed as a planarization process to etch the polysilicon layer. As a result, a plurality of storage node contact plugs 36 are formed inside the first storage node contact holes 34A.

The etch back process performed on the polysilicon layer to form the storage node contact plugs 36 includes using a chlorine-based gas. For instance, the etch back process includes using a Cl₄ gas. If the etch back process is performed using the Cl₄ gas, the polysilicon layer is etched faster than the first patterned insulation layer 32A.

As shown in FIG. 3D, an over etch process is performed to remove residues of the polysilicon layer remaining over the first patterned insulation layer 32A. The over etch process is employed to minimize damage on the storage node contact plugs 36 and to increase an etch rate of the first patterned insulation layer 32A. Accordingly, the first patterned insulation layer 32A disposed between the storage node contact plugs 36, i.e., each of widened top portions of the storage node contact plugs 36, has a vertical etch profile by increasing the etch rate of the first patterned insulation layer 32A. The insulation layer having the vertical etch profile is referred to as a second patterned insulation layer and denoted with a reference numeral 32B. The storage node contact holes, and the storage node contact plugs, each having vertical profiles are respectively referred to as second storage node contact holes denoted with a reference numeral 34B, and first storage node contact plugs denoted with a reference numeral 36A.

The over etch process includes using a fluorine-based gas. For instance, the fluorine-based gas can be selected from a group consisting of tetrafluoromethane (CF₄), trifluoromethane (CHF₃), and hexafluorocyclobutene (C₄F₆). The fluorine-based gas combines with a carbon gas. Also, a small amount of an oxygen gas is added to the fluorine-based gas. An etch rate of the polysilicon layer is controlled adding the oxygen gas to the fluorine-based gas. The storage node contact plugs 36 are selectively etched using the fluorine-based gas including the oxygen gas to obtain the first storage node contact plugs 36A.

A gas which does not include a carbon component makes the etch rate of the polysilicon layer faster and thus, cannot control an etch loss generated on the polysilicon layer. Accordingly, the fluorine-based gas including the carbon component is used as a main gas to control the etch rate of the polysilicon layer.

During the over etch process, the mixture gas of the fluorine-based gas and the oxygen gas has a total flow rate ranging from about 30 sccm to about 150 sccm. A flow rate of the oxygen gas corresponds to about 1% to about 10% of the total flow rate of the mixture gas. If the oxygen gas having a flow rate greater than about 10% of the total flow rate of the mixture gas is implanted, the etch rate of the polysilicon layer is faster. As a result, an excessive etch loss can be induced on the storage node contact plugs 36, and the storage node contact plugs 36 can hardly obtain the gradually sloping profiles.

If the over etch process is performed using the mixture gas of the fluorine-based gas and the oxygen gas, the etch rate of the first patterned insulation layer 32A has an etch selectivity faster than the polysilicon layer used to form the storage node contact plugs 36. The etch selectivity between the first patterned insulation layer 32A and the storage node contact plugs 36 is maintained in a ratio of about 1.5 to 3 parts of the first patterned insulation layer 32A: about 1 part of the polysilicon layer.

During the etch back process of the polysilicon layer performed to form the storage node contact plugs 36, the etch rate of the polysilicon layer formed inside the first storage node contact holes 34A is relatively faster than that of the first patterned insulation layer 32A. Accordingly, the top portions of the second storage node contact holes 34B can have the gradually sloping profiles only if the above mentioned etch selectivity is maintained during performing the over etch process.

As a result of the over etch process, certain portions of the first patterned insulation layer 32A, i.e., the damaged top portions of the first storage node contact holes 34A denoted with dotted lines, are etched. An initial height H31 (see FIG. 3C) of the first patterned insulation layer 32A is reduced to obtain a height H32 of the second patterned insulation layer 32B. Accordingly, the damaged top portions of the first storage node contact holes 34A are removed. While the first patterned insulation layer 32A disposed between the storage node contact plugs 36 has a line width S4, the second patterned insulation layer 32B between the first storage node contact plugs 36A maintains a line width S3 initially defined when the storage node contact holes 34 are formed. The etch back process and the over etch process are performed at a radio frequency (RF) plasma chamber or a microwave plasma chamber.

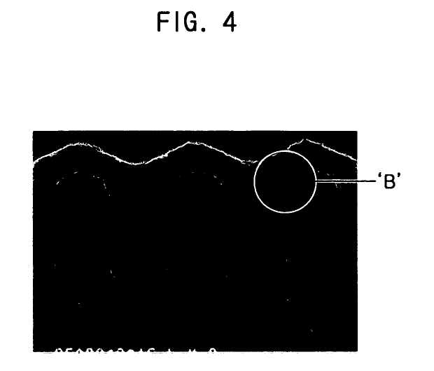

FIG. 4 illustrates an improved storage node contact plug in accordance with another embodiment of the present invention. A reference letter ‘B’ shows a stable top profile of a storage node contact plug. Since an etch rate of a polysilicon layer is faster than an insulation layer, an etch loss generated on the polysilicon layer inside a storage node contact hole is controlled during an over etch process. As a result, the storage node contact plug can obtain the stable top profile.

As described above, during etching the polysilicon layer to form the storage node contact plug, the etch back process is initially performed using the chlorine-based gas. Then, an over etch process is performed using a mixture gas of the fluorine-based gas and the oxygen gas which provides a difference in the etch rate between the insulation layer and the polysilicon layer.

The etch back process and the over etch process minimize an etch loss on the polysilicon layer used to form the storage node contact plug and induce an excessive etch loss on the insulation layer. As a result, the top portion of the storage node contact hole can have a vertical shape. Accordingly, an overlay margin between the storage node contact plug and a subsequent storage node hole can be secured.

While the present invention has been described with respect to the specific embodiments, it will be apparent to those skilled in the art that various changes and modifications may be made without departing from the spirit and scope of the invention as defined in the following claims. Although forming the storage node contact holes and storage node contact plugs are illustrated in the specific embodiments, the illustrated and described embodiments can be applied to form other types of contact holes and contact plugs.

What is claimed is:

1. A method for fabricating a contact plug of a semiconductor device, comprising:
forming an insulation layer over a substrate;
forming a hard mask over the insulation layer;
etching the insulation layer to form a contact hole;
removing the hard mask;
forming a conductive layer to fill the contact hole;
performing an etch back process on the conductive layer to form a contact plug; and
performing an over etch process.

2. The method of claim 1, wherein performing the etch back process comprises etching the insulation layer faster than the conductive layer.

3. The method of claim 1, wherein performing the over etch process comprises maintaining a ratio of an etch selectivity of the insulation layer to that of the contact plug at about 1.5-3:1.

4. The method of claim 3, wherein the conductive layer includes a polysilicon layer; and the insulation layer includes an oxide-based layer.

5. The method of claim 4, wherein performing the etch back process comprises using a chlorine-based gas.

6. The method of claim 4, wherein performing the over etch process comprises using a fluorine-based gas combined with carbon.

7. The method of claim 6, wherein the fluorine-based gas includes one selected from a group consisting of tetrafluoromethane (CF₄), trifluoromethane (CHF₃), and hexafluorocyclobutene (C₄F₆).

8. The method of claim 6, wherein performing the over etch process comprises using a mixture gas obtained by adding an oxygen gas to the fluorine-based gas.

9. The method of claim 8, wherein the mixture gas flows at a rate ranging from about 30 sccm to about 150 sccm.

10. The method of claim 9, wherein a flow rate of the oxygen gas corresponds to about 1% to 10% of the total flow rate of the mixture gas.

11. The method of claim 4, wherein the etch back process and the over etch process are performed in one of a radio frequency (RF) plasma chamber and a microwave plasma chamber.

12. The method of claim 1, wherein removing the hard mask includes:
forming a photoresist layer over the insulation layer and inside the contact hole;
performing an etch back process on the photoresist layer to remove the hard mask; and
removing the photoresist layer remaining inside the contact hole.

13. The method of claim 12, wherein the hard mask includes a silicon rich oxynitride (SRON) layer.

14. The method of claim 1, wherein the contact hole includes a storage node contact hole; and the contact plug includes a storage node contact plug.

15. The method of claim 1, wherein performing the over etch process comprises etching the insulation layer faster than the contact plug.
